(19) United States
(12) Patent Application Publication
(10) Pub. No.: US 2002/0190298 A1
(43) Pub. Date: Dec. 19, 2002

(54) Trench capacitor of a dram memory cell with a metallic collar region and a non-metallic buried strap to a selection transistor

(76) Inventors: Johann Alsmeier, Radebeul (DE); Martin Gutsche, Dorfen (DE); Bernhard Sell, Dresden (DE); Annette Sanger, Dresden (DE); Harald Seidl, Feldkirchen (DE)

Correspondence Address: LERNER AND GREENBERG, P.A., Post Office Box 2480, Hollywood, FL, 33022-2480, US

(21) Appl. No.: 10/170,312

(22) Filed: Jun. 13, 2002

(30) Foreign Application Priority Data
Jun. 13, 2001 (DE) 101 28 718.6

(51) Int. Cl. H01L 27/108

(52) U.S. Cl. 257/301

(57) ABSTRACT

A memory cell has a selection transistor and a trench capacitor. An upper capacitor electrode of the trench capacitor, in the region of an insulating collar, has a metallic section, and that section of the upper electrode that makes contact with a storage dielectric is of a non-metallic form, in particular containing polysilicon. A buried strap, which connects the upper electrode to the select transistor, is of a non-metallic form, in particular formed of polysilicon.

### BACKGROUND OF THE INVENTION

### FIELD OF THE INVENTION

The present invention relates to a memory cell and to a method for its fabrication. The memory cell has a substrate, into which a trench capacitor and a selection transistor, which is electrically connected to the trench capacitor by a buried strap, are formed. In the memory cell, the trench capacitor has a trench and is formed from a lower capacitor electrode, which adjoins a wall of the trench in the lower region of the trench, a storage dielectric and an upper capacitor electrode. The upper capacitor electrode is in the form of a trench filling introduced above the storage dielectric. A spacer layer, which adjoins a wall of the trench, is provided in an upper section of the trench.

In dynamic random access memory cell configurations, virtually exclusively single-transistor memory cells are used. A single-transistor memory cell contains a read transistor and a storage capacitor. The information is stored in the storage capacitor in the form of an electric charge that represents a logic 0 or a logic 1. Actuating the read transistor via a word line allows the information to be read via a bit line. The storage capacitor must have a minimum capacitance for reliable storage of the charge and, at the same time, to make it possible to differentiate the information item that has been read. A lower limit for the capacitance of the storage capacitor is currently considered to be 25 fF.

Since the storage density increases from memory generation to memory generation, the surface area required by the single-transistor memory cell must be reduced from generation to generation. At the same time, the minimum capacitance of the storage capacitor has to be retained.

Up to the 1 Mbit generation, both the read transistor and the storage capacitor have been produced as planar components. Beyond the 4 Mbit memory generation, the area taken up by the memory cell was reduced further by using a three-dimensional configuration of the read transistor and the storage capacitor. One possibility is for the capacitor to be produced in a trench (see for example the reference by K. Yamada et al., Proc. Intern. Electronic Devices and Materials IEDM 85, pp. 702). In this case, a diffusion region that adjoins the wall of the trench and a doped polysilicon filling disposed in the trench act as electrodes for the storage capacitor. Therefore, the electrodes of the storage capacitor are disposed along the surface of the trench. In this way, the effective surface area of the storage capacitor, on which the capacitance is dependent, is increased with respect to the space taken up by the storage capacitor on the surface of the substrate, which corresponds to the cross section of the trench. Although there are limits on the extent to which the depth of the trench can be increased, for technological reasons, the packing density can be further increased by reducing the cross section of the trench.

However, one difficulty of the decreasing trench cross section is the increasing electrical resistance of the trench filling and the associated increase in the read-out time of the DRAM memory cell. Therefore, to ensure a high read-out speed as the trench cross section is further reduced in size, it is necessary to select materials with a lower resistivity as electrodes of the trench capacitor. In current trench capacitors, the trench filling is formed of doped polycrystalline silicon, so that as miniaturization continues a high series resistance of the trench filling results.

There have already been various proposals for depositing a metal or a sequence of layers that includes a metal-containing layer in the trench. U.S. Pat. No. 5,905,279 discloses a memory cell having a storage capacitor disposed in a trench and a selection transistor, in which the storage capacitor has a lower capacitor electrode, which adjoins a wall of the trench, a capacitor dielectric and an upper capacitor electrode. The upper capacitor electrode contains a layer stack including polysilicon, a metal-containing, electrically conductive layer, in particular made from WSi, TiSi, W, Ti or TiN, and polysilicon. The trench capacitor is fabricated by first forming the upper capacitor electrode in the lower trench region. Then, an insulating collar is deposited in the upper trench region, and next the upper capacitor electrode is completed. Alternatively, the method is carried out on a silicon on insulator (SOI) substrate which does not have an insulating collar, in which case the upper capacitor electrode, which contains a lower polysilicon layer and a tungsten silicide filling, is fabricated in a single-step deposition method, in which the individual layers are deposited entirely in the trench. However, the reduction in the series resistance of the upper capacitor electrode that can be achieved with this method is as yet unsatisfactory.

Published, European Patent Application EP 0 981 158 A2, on which the preamble is based, describes the fabrication of a DRAM memory cell which includes a trench capacitor and a selection transistor which is connected to the trench capacitor via a buried strap. The trench capacitor has a lower capacitor electrode, which adjoins a wall of the trench, a capacitor dielectric and an upper capacitor electrode. The trench capacitor is fabricated by first forming the upper capacitor electrode in the lower trench region, depositing an insulating collar on the upper capacitor electrode in the upper trench region, and then completing the upper capacitor electrode. With regard to the trench filling, which forms the upper capacitor electrode, it is specifically stated that the filling may be formed by a metal both in the lower region of the trench and in the upper region of the insulating collar. In this case, however, the trench filling in the region of the insulating collar is formed in one operation and therefore from the same material as the buried strap. Therefore, if a metal is formed into the insulating collar, the buried strap is inevitably also formed from metal. However, it is also possible that the select transistor may be adversely affected by the contact with a highly conductive material at the drain region.

### SUMMARY OF THE INVENTION

It is accordingly an object of the invention to provide a trench capacitor of a DRAM memory cell with a metallic collar region and a non-metallic buried strap to the selection transistor which overcomes the above-mentioned disadvantages of the prior art devices of this general type, in which the trench capacitor has a reduced series resistance without adversely affecting the select transistor.

With the foregoing and other objects in view there is provided, in accordance with the invention, a memory cell. The memory cell contains a substrate having a trench formed therein and defined by walls. A trench capacitor is disposed in the trench. The trench capacitor has a lower capacitor electrode adjoining one of the walls of the trench in a lower region of the trench, a storage dielectric, and an upper capacitor electrode in a form of a trench filling disposed above the storage dielectric. The trench filling has a first section making contact with the storage dielectric and the first section is non-metallic. A non-metallic buried strap is provided. A selection transistor is formed in the substrate and is connected to the trench capacitor through the non-metallic buried strap. A spacer layer adjoins one of the walls of the trench and is disposed in an upper region of the trench. The trench filling has a second section disposed inside the spacer layer and is formed of metal, metal silicide, or metal nitride.

The invention is based on the memory cell having the trench capacitor, in which the trench is formed in the substrate, and the upper capacitor electrode, which adjoins a wall of the trench in the lower trench region, the storage dielectric and the upper capacitor electrode in the form of a trench filling disposed above the dielectric are provided. A significant aspect of the memory cell according to the invention relates in the fact that that section of the trench filling of the trench capacitor that makes contact with the storage dielectric is non-metallic. In contrast, the trench filling, in a section inside the insulating collar, is formed by metal, a metal silicide, or a metal nitride, and the buried strap is nonmetallic.

With this combination of features, it is possible to achieve the object of the invention, namely that of producing a series resistance of the trench filling which is as low as possible, yet at the same time certain additional conditions can be satisfied.

According to the invention, only part of the trench is filled with metal, while that section of the trench filling which makes contact with the storage dielectric is non-metallic and is formed, for example, by doped polycrystalline silicon (“polysilicon”). Although this does not reduce the series resistance as much as a continuous metal filling in the trench, the metal is not in direct contact with the dielectric. The spatial separation results in that the dielectric cannot be impaired in any way by adjoining metal during conditioning processes or in any other way.

A significant idea of the invention relates to the measure of forming the trench filling, in a section inside the insulating collar, known as the collar region, from metal, a metal silicide or a metal nitride, and thereby making it highly electrically conductive. This is because the collar region, on account of its small cross section, makes a particularly high contribution to the series resistance of the trench filling, with the result that a low-resistance layer is particularly desirable in this region.

In one embodiment, polysilicon is deposited in the entire lower region of the trench, i.e. in the region below the insulating collar, and metal is only introduced within the insulating collar. This has the advantage, in terms of process engineering, that the demands on the metal deposition are lower than if the trench is completely filled with metal, since the aspect ratios can still be dealt with relatively easily. However, it is theoretically also possible for only a relatively thin layer of polysilicon to be deposited on the dielectric and then for the trench to be filled with metal substantially up to the intended buried strap.

According to the invention, there is provision for at least a section of the interior of the insulating collar to be filled with metal, metal silicide, or metal nitride. It will be clear that, to achieve the lowest possible series resistance, this section should be as large as possible. In the optimum scenario, this section should extend over the entire length of the insulating collar, so that the entire narrow collar region would be filled with a highly electrically conductive material.

A further aspect of the invention resides in the fact that the buried strap, which produces the connection to the selection transistor, is processed separately from the collar region and therefore can be fabricated from a different material from the collar region. Therefore, the buried strap may be formed from a material with a lower electrical conductivity, so that the selection transistor is not adversely affected. Low-doped polysilicon is selected as a preferred material for the buried strap.

The metal that is deposited in the collar region may, for example, be formed by tungsten or tungsten silicide.

In accordance with an added feature of the invention, the first section of the trench filling is formed of a doped polycrystalline silicon. The second section of the trench filling is formed of tungsten, titanium, molybdenum, tantalum, cobalt, nickel, niobium, platinum, palladium, rare earths, a silicide or a nitride formed from one of above mentioned metals.

In accordance with a further feature of the invention, the non-metallic buried strap is formed from doped polycrystalline silicon.

With the foregoing and other objects in view there is provided, in accordance with the invention, a method for fabricating a memory cell. The method includes providing a substrate, forming a trench in the substrate, forming a spacer layer from an insulating material in an upper trench region of the trench, providing a lower capacitor electrode adjoining a wall of the trench in a lower trench region of the trench, providing a storage dielectric in the trench, and forming an upper capacitor electrode by introducing a trench filling into the trench. The trench filling has a non-metallic first section making contact with the storage dielectric, and a second section disposed inside the spacer layer. The second section is formed of metal, metal silicide, or metal nitride. A non-metallic buried strap is formed in the trench, and a selection transistor having a source electrode, a drain electrode, a gate electrode and a conductive channel are formed on and in the substrate. The source electrode or the drain electrode is connected in an electrically conductive manner to the upper capacitor electrode by the non-metallic buried strap.

With the foregoing and other objects in view there is further provided, in accordance with the invention, a method for fabricating a memory cell. The method includes providing a substrate, forming a trench in the substrate, providing a lower capacitor electrode adjoining a wall of the trench in a lower trench region of the trench, providing a storage dielectric in the trench, and forming an upper capacitor electrode by introducing a trench filling into the trench. The trench filling is non-metallic in a first section making contact with the storage dielectric. A spacer layer formed from an insulating material is provided in an upper trench region. A second section of the upper capacitor electrode is formed by introducing a metal, a metal silicide or a metal nitride within the spacer layer. A non-metallic buried strap is formed in the trench. A selection transistor having a source electrode, a drain electrode, a gate electrode and a conductive channel is formed in and on the substrate. The source electrode or the drain electrode is connected in an electrically conductive manner to the upper capacitor electrode by the non-metallic buried strap.

Other features which are considered as characteristic for the invention are set forth in the appended claims.

Although the invention is illustrated and described herein as embodied in a trench capacitor of a DRAM memory cell with a metallic collar region and a non-metallic buried strap to a selection transistor, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1-7 are diagrammatic, sectional views showing the individual steps of a first variant embodiment of the fabrication of a memory cell according to the invention; and

FIGS. 8 and 9 are sectional views showing intermediate steps of a second variant embodiment of the fabrication of the memory cell.

### DESCRIPTION OF THE PREFERRED EMBODIMENTS

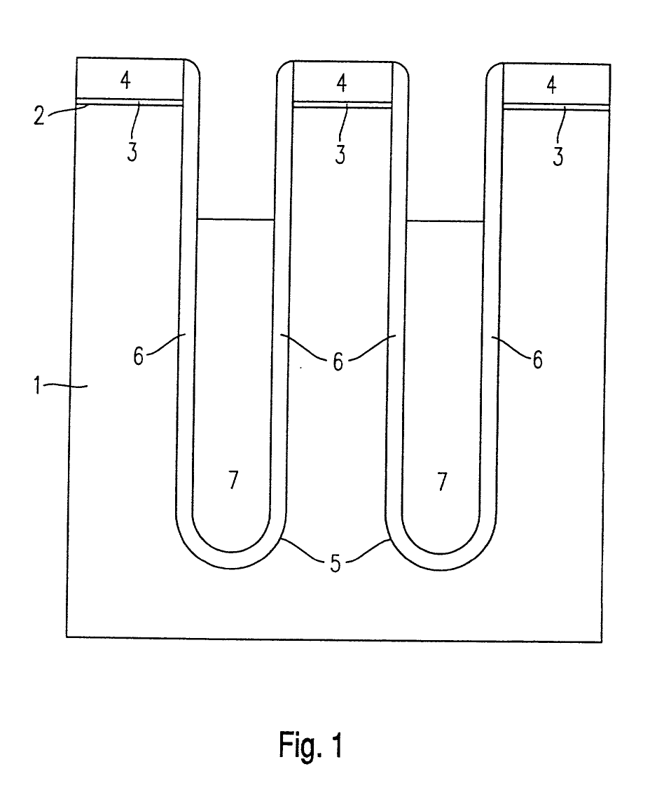

Referring now to the figures of the drawing in detail and first, particularly, to FIG. 1 thereof, there is shown a silicon substrate 1 with a main surface 2. A 5 nm thick SiO₂ layer 3 and a 200 nm thick Si₃N₄ layer 4 are applied to the main surface 2. Then, a 1000 nm thick non-illustrated BSG layer is applied as a hard mask material.

Using a non-illustrated mask produced by photolithography, the BSG layer, the Si₃N₄ layer 4 and the SiO₂ layer 3 are patterned in a plasma etching process using CF₄/CHF₃, so that a hard mask is formed. After removal of the mask produced by photolithography, trenches 5 are etched into the main surface 1 in a further plasma etching process using HBr/NF₃ and the hard mask as an etching mask. Then, the BSG layer is removed by a wet etch using H₂SO₄/HF.

The depth of the trenches 5 is, for example, 5 μm, their width is 100×250 nm and they are spaced apart from one another by 100 nm.

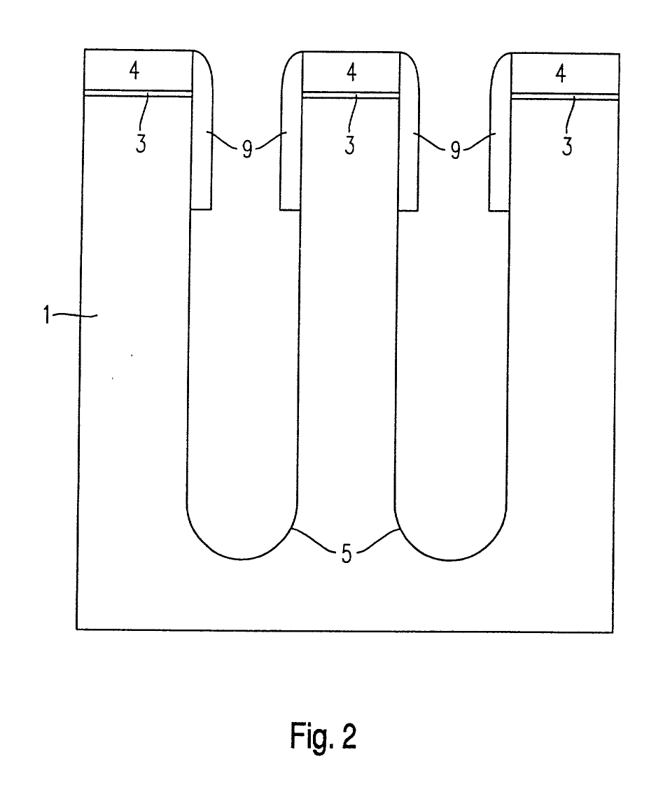

Next, a 10 nm thick SiO₂ layer 6, which may also be doped, for example by in-situ doping, is deposited. The deposited SiO₂ layer 6 covers at least the walls of the trenches 5. Deposition of a 200 nm thick polysilicon layer, chemical mechanical polishing down to the surface of the Si₃N₄ layer 4 and etching back of the polysilicon layer using SF₆ results in a polysilicon filling 7 being produced in each of the trenches 5, the surface of which polysilicon filling is disposed 1000 nm below the main surface 2. If appropriate, the chemical mechanical polishing can be dispensed with. The polysilicon filling 7 is used as a sacrificial layer for the subsequent Si₃N₄ spacer deposition. Next, the SiO₂ layer 6 on the walls of the trenches 5 is etched isotropically (see FIG. 2).

Then, a chemical vapor deposition (CVD) process is used to deposit a 20 nm thick spacer layer 9, which contains silicon nitride and/or silicon dioxide, and the spacer layer 9 is then etched in an anisotropic plasma etching process using CHF₃. The spacer layer 9 that has just been deposited is used, in the finished memory cell, to disconnect the parasitic transistor that would otherwise form at this location, and therefore forms an insulating collar 9.

Then, SF₆ is used to etch polysilicon selectively with respect to Si₃N₄ and SiO₂. In the process, the polysilicon filling 7 is in each case removed completely from the trench 5. That part of the SiO₂ layer that has now been uncovered is removed by etching using NH₄F/HF (see FIG. 2).

If appropriate, to widen the trenches 5 in their lower region, i.e. in the region remote from the main surface 2, silicon is then etched selectively with respect to the spacer layer 9. This is affected, for example, by an isotropic etching step using ammonia, in which the silicon is etched selectively with respect to Si₃N₄. The etching time is such that 20 nm of silicon are etched. In this way, the cross section is widened by 40 nm in the lower region of the trenches 5. As a result, the capacitor area and therefore the capacitance of the capacitor can be increased further. The collar 9 may also be produced by other processes, such as for example local oxidation (LOCOS) or collar formation during the trench etching.

The drawings illustrate the process sequence with unwidened trenches.

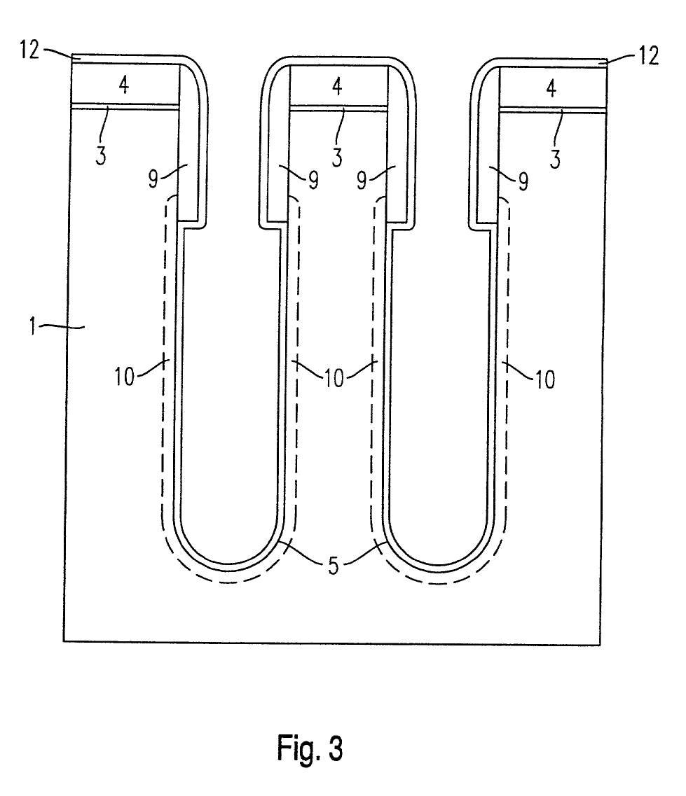

Then, if this has not already been affected by the doped oxide, the silicon substrate 1 is doped. This can be achieved, for example, by depositing an arsenic-doped silicate glass layer in a layer thickness of 50 nm and a TEOS-SiO₂ layer in a thickness of 20 nm, followed by a heat treatment step at 1000° C., 120 seconds, with the result that, as a result of diffusion out of the arsenic-doped silicate glass layer, an n-doped region 10 is formed in the silicon substrate 1 (FIG. 3). Alternatively, it is also possible to carry out vapor-phase doping, for example using the following parameters: 900° C., 399 Pa, tributylarsine (TBA) [33 percent], 12 min.

A first object of the n⁺-doped region 10 is to reduce the size of the depletion zone, so that the capacitance of the capacitor is increased further. Second, the high doping concentration, which is of the order of magnitude of 10¹⁹ cm⁻³, allows the lower capacitor electrode to be provided, if it is not to be metallic. If it is metallic, the high level of doping produces an ohmic contact. The required doping for the ohmic contact is approximately 5×10¹⁹ cm⁻³.

Alternatively, the lower capacitor electrode may also be produced by deposition of an electrically conductive layer, as has been described, for example, in Published, Non-Prosecuted German Patent Application DE 199 44 012 A.

Next, a 5 nm thick dielectric layer 12, which contains SiO₂ and Si₃N₄ and also, if appropriate, silicon oxynitride, is deposited as a capacitor dielectric 12. The layer sequence can be realized by steps of nitride deposition and of thermal oxidation, in which defects in the layer below are annealed. As an alternative, the dielectric layer 12 contains Al₂O₃ (aluminum oxide), TiO₂ (titanium dioxide), TaO₅ (tantalum oxide). In any event, the capacitor dielectric 12 is deposited over the entire surface, so that it completely covers the trench 5 and the surface of the silicon nitride layer 4 (see FIG. 3).

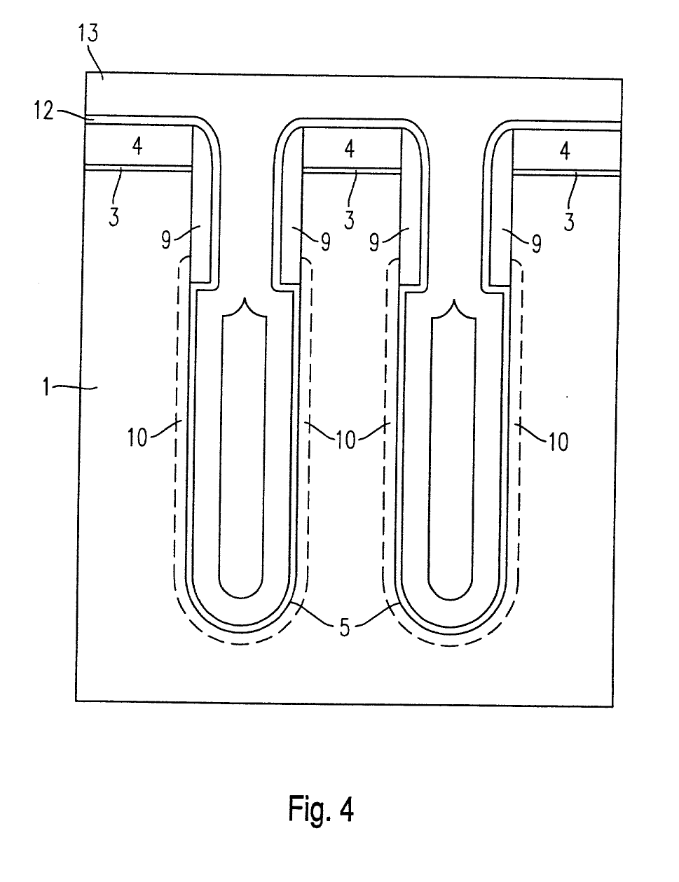

Then, in FIG. 4, the formation of an upper capacitor electrode 18 begins. First, an approximately 200 nm thick in-situ doped polysilicon layer 13 is deposited. As can be seen, a cavity is formed in a lower region of the trench during the deposition of the polysilicon layer 13.

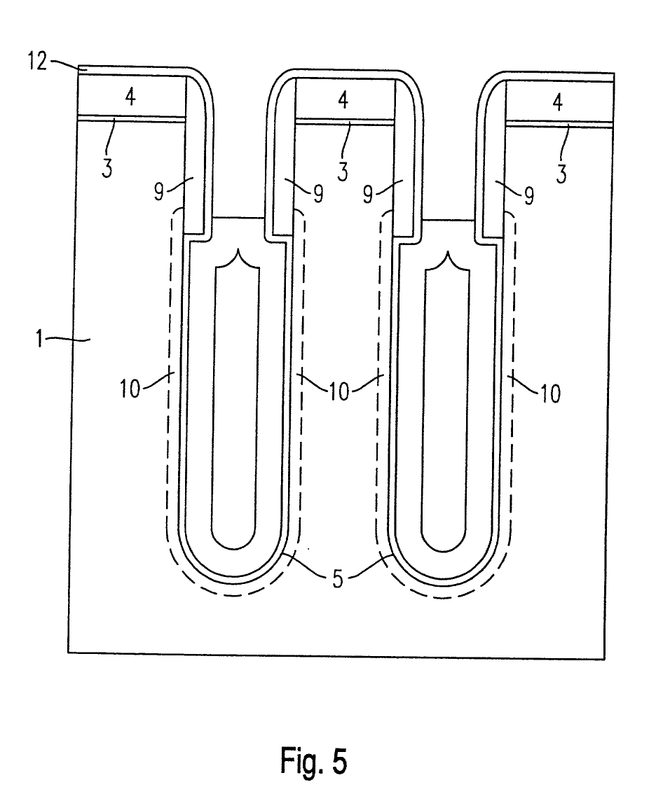

Then, the polysilicon layer 13 is isotropically etched back, for example by plasma etching using SF₆, so that the polysilicon is removed again until just above a lower edge of the insulating collar 9, as can be seen from FIG. 5.

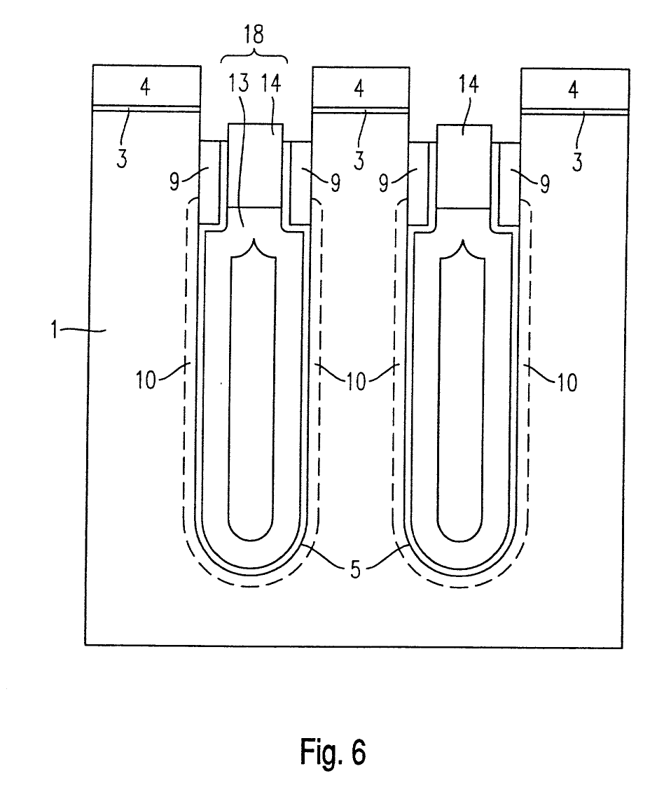

Then, a metal layer is deposited and is etched back isotropically, for example using SF₆, so that it remains as a metal plug 14 in the upper region of the trench 5 (see FIG. 6).

Then, the insulating collar 9 and the dielectric 12 are etched back isotropically to below the surface of the metal plug 14, resulting in the structure shown in FIG. 6. This can take place, for example, by wet-chemical etching using H₃PO₄ and HF.

Then, a DRAM process is carried out, by which the upper capacitor electrode 18 is suitably structured and connected to a source/drain region of a selection transistor. Of course, the selection transistor may also be produced as a vertical transistor.

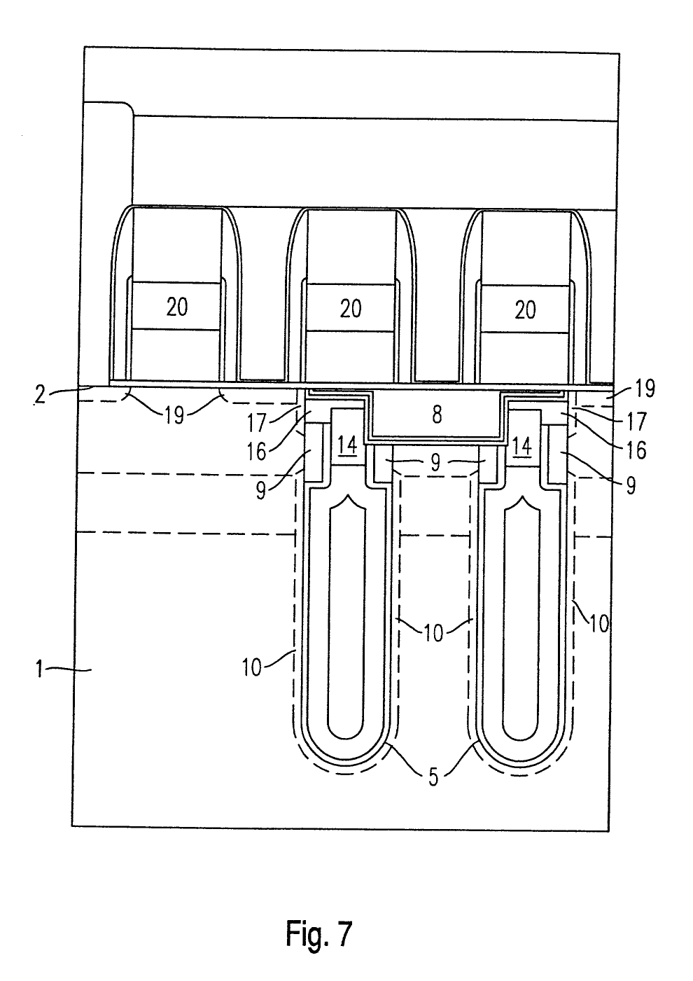

After a sacrificial oxidation step in order to form a non-illustrated screen oxide, an implantation is carried out, in which an n-doped region 17 is formed in the side wall of each trench 5 in the region of the main surface 2. As shown in FIG. 7, a free space that is left above the upper capacitor electrode 18 in the respective trench 5 is filled with a polysilicon filling 16 by deposition of polysilicon that is doped in situ and by etching back the polysilicon using SF₆. The low-doped polysilicon filling 16 acts as a connection structure or so-called buried strap 16 between the n-doped region 17 and the metal plug 14 of the upper capacitor electrode 18.

Next, insulating structures 8 are produced, which surround the active regions and thereby define the active regions. For this purpose, a mask is formed, which defines the non-illustrated active regions. The insulating structures 8 are completed by non-selective plasma etching of silicon, SiO₂ and polysilicon with the aid of CHF₃/N₂/NF₃, the etching time being set in such a way that 200 nm of polysilicon are etched, by removal of the resist mask used by O₂/N₂, by wet-chemical etching of 3 nm of the dielectric layer, by oxidation and deposition of a 5 nm thick Si₃N₄ layer and by deposition of a 250 nm thick SiO₂ layer in a TEOS process and subsequent chemical mechanical polishing. Then, the Si₃N₄ layer 4 is removed by etching in hot H₃PO₄ and the SiO₂ layer 3 is removed by etching in dilute hydrofluoric acid.

Next, a screen oxide is formed by sacrificial oxidation. This step uses implantation stages and masks produced by photolithography in order to form n-doped wells, p-doped wells and to carry out threshold voltage implantations in the regions of the periphery and of the select transistors of the cell array. Furthermore, a high-energy ion implantation is carried out in order to dope the substrate region that is remote from the main surface 2. In this way, an n⁺-doped region, which connects adjacent lower capacitor electrodes to one another, is formed (known as a “buried-well implant”).

Next, the transistor is completed using generally known method steps, by in each case defining the gate oxide and gate electrodes 20, corresponding interconnects and source and drain electrodes 19.

Then, the memory cell is completed in a known way by the formation of further wiring planes.

In the variant embodiment that is described in FIGS. 1 to 7, the spacer layer 9 is formed first, and then the polysilicon is introduced into the trench 5.

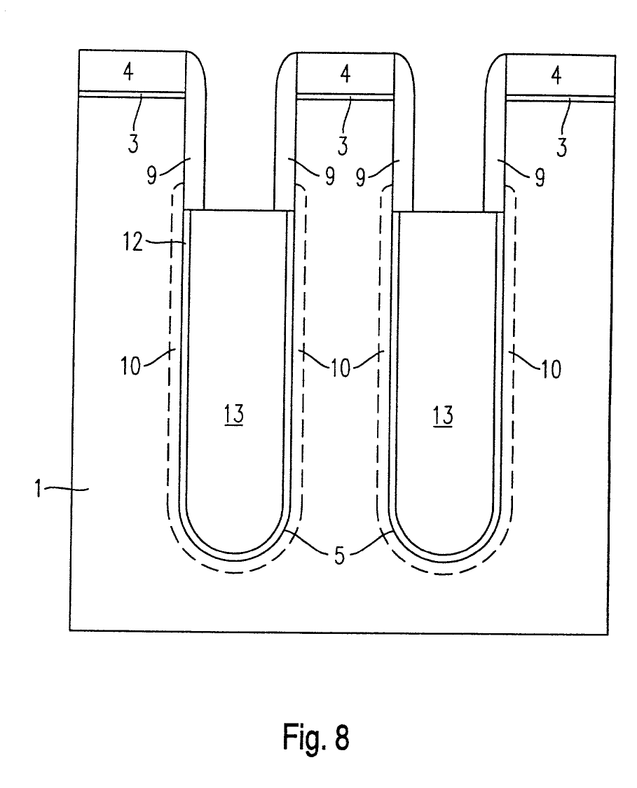

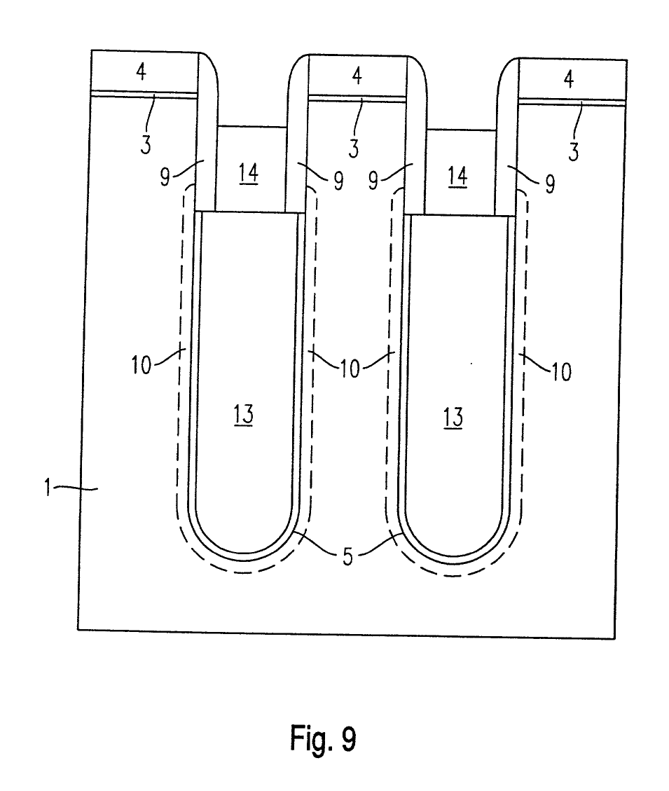

FIGS. 8 and 9 show an alternative variant embodiment, in which the polysilicon is introduced into the trench 5, and then the spacer layer 9 is formed.

First, the trenches 5 are produced in the main surface of the substrate 1 in the same way as that which has already been described in connection with the first variant embodiment.

Then, in a multistage process (TEAS deposition, followed by resist fill, resist recess etching, TEAS removal in the upper region, TEOS deposition with a subsequent conditioning step, oxide strip, NO (dielectric) and polysilicon deposition with subsequent poly-recess), the trench 5 with the dielectric 12 and the polycrystalline silicon 13 is formed up to a predetermined height in the upper trench region. Then, above this, the spacer layer 9 is deposited, resulting in the structure shown in FIG. 8.

Next, a metal is deposited and etched back isotropically, so that metal plugs 14 remain inside the collar 9, as shown in FIG. 9.

After the collar 9 has been etched back, the DRAM process can then be carried out in principle as shown in FIG. 7 with the upper part of the metal plug 14 connected to the buried strap 16 made from low-doped polycrystalline silicon.

As can be seen from FIG. 9, one advantage of the second variant embodiment is that the metal plug 14 extends precisely to the lower edge of the collar 9, while in the first variant embodiment the etching stop cannot be controlled as accurately during the poly-recess etching when the collar 9 is already present.

We claim:

1. A memory cell, comprising:
a substrate having a trench formed therein and defined by walls;
a trench capacitor disposed in said trench, said trench capacitor having a lower capacitor electrode adjoining one of said walls of said trench in a lower region of said trench, a storage dielectric, and an upper capacitor electrode in a form of a trench filling disposed above said storage dielectric, said trench filling having a first section making contact with said storage dielectric and said first section being non-metallic;
a non-metallic buried strap;
a selection transistor formed in said substrate and connected to said trench capacitor through said non-metallic buried strap; and
a spacer layer adjoining one of said walls of said trench and disposed in an upper region of said trench, said trench filling having a second section disposed inside said spacer layer and formed of a material selected from the group consisting of metal, metal silicide, and metal nitride.

2. The memory cell according to claim 1, wherein said first section of said trench filling is formed of a doped polycrystalline silicon.

3. The memory cell according to claim 1, wherein said second section of said trench filling is formed of a material selected from the group consisting of tungsten, titanium, molybdenum, tantalum, cobalt, nickel, niobium, platinum, palladium, rare earths, a silicide formed from one of tungsten, titanium, molybdenum, tantalum, cobalt, nickel, niobium, platinum, palladium, and rare earths, and a nitride formed from one of tungsten, titanium, molybdenum, tantalum, cobalt, nickel, niobium, platinum, palladium, and rare earths.

4. The memory cell according to claim 1, wherein said non-metallic buried strap is formed from doped polycrystalline silicon.

5. A method for fabricating a memory cell, which comprises the steps of:
providing a substrate;
forming a trench in the substrate;
forming a spacer layer from an insulating material in an upper trench region of the trench;
providing a lower capacitor electrode adjoining a wall of the trench in a lower trench region of the trench;
providing a storage dielectric in the trench;
forming an upper capacitor electrode by introducing a trench filling into the trench, the trench filling having a non-metallic first section making contact with the storage dielectric, and a second section disposed inside the spacer layer, the second section formed of a material selected from the group consisting of metal, metal silicide, and metal nitride;
forming a non-metallic buried strap in the trench; and
forming a selection transistor having a source electrode, a drain electrode, a gate electrode and a conductive channel on and in the substrate, one of the source electrode and the drain electrode being connected in an electrically conductive manner to the upper capacitor electrode by the non-metallic buried strap.

6. The method according to claim 5, which comprises forming the non-metallic first section of the trench filling which makes contact with the storage dielectric with a doped polycrystalline silicon.

7. The method according to claim 5, which comprises forming the second section inside the spacer layer from a material selected from the group consisting of tungsten, titanium, molybdenum, tantalum, cobalt, nickel, niobium, platinum, palladium, rare earths, a silicide formed from one of tungsten, titanium, molybdenum, tantalum, cobalt, nickel, niobium, platinum, palladium, and rare earths, and a nitride formed from one of tungsten, titanium, molybdenum, tantalum, cobalt, nickel, niobium, platinum, palladium, and rare earths.

8. The method according to claim 5, which comprises forming the non-metallic buried strap from doped polycrystalline silicon.

9. A method for fabricating a memory cell, which comprises the steps of:
providing a substrate;
forming a trench in the substrate;
providing a lower capacitor electrode adjoining a wall of the trench in a lower trench region of the trench;
providing a storage dielectric in the trench;
forming an upper capacitor electrode by introducing a trench filling into the trench, the trench filling being non-metallic in a first section making contact with the storage dielectric;
forming a spacer layer from an insulating material in an upper trench region;
producing a second section of the upper capacitor electrode by introducing a material selected from the group consisting of metal, a metal silicide and a metal nitride within the spacer layer;
forming a non-metallic buried strap in the trench;
forming a selection transistor having a source electrode, a drain electrode, a gate electrode and a conductive channel in and on the substrate, one of the source electrode and the drain electrode being connected in an electrically conductive manner to the upper capacitor electrode by the non-metallic buried strap.

10. The method according to claim 9, which comprises forming the first section of the trench filling which makes contact with the storage dielectric from a doped polycrystalline silicon.

11. The method according to claim 9, which comprises forming the second section inside the spacer layer from a material selected from the group consisting of tungsten, titanium, molybdenum, tantalum, cobalt, nickel, niobium, platinum, palladium, rare earths, a silicide formed from one of tungsten, titanium, molybdenum, tantalum, cobalt, nickel, niobium, platinum, palladium, and rare earths, and a nitride formed from one of tungsten, titanium, molybdenum, tantalum, cobalt, nickel, niobium, platinum, palladium, and rare earths.

12. The method according to claim 9, which comprises forming the non-metallic buried strap from doped polycrystalline silicon.
